(19) United States
(12) Patent Application Publication
(10) Pub. No.: US 2007/0217466 A1
(43) Pub. Date: Sep. 20, 2007

(54) Two-dimensional photonic crystal surface light emitting laser

(75) Inventors: Susumu Noda, Kyoto-shi (JP); Eiji Miyai, Kyoto-shi (JP); Kyosuke Sakai, Kyoto-shi (JP); Dai Ohnishi, Kyoto-shi (JP); Wataru Kunishi, Kyoto-shi (JP)

Correspondence Address: OLIFF & BERRIDGE, PLC, P.O. BOX 19928, ALEXANDRIA, VA, 22320, US

(73) Assignees: ROHM CO., LTD., KYOTO-SHI (JP); KYOTO UNIVERSITY, KYOTO-SHI (JP)

(21) Appl. No.: 11/723,170

(22) Filed: Mar. 16, 2007

(30) Foreign Application Priority Data
Mar. 20, 2006 (JP) 2006-077470 (P)

(51) Int. Cl. H01S 5/00

(52) U.S. Cl. 372/50.11

(57) ABSTRACT

A surface-emitting laser according to the present invention includes a laminated body between a first electrode 471 and a second electrode 472. The laminated body includes an active layer 43 and a two-dimensional photonic crystal 45. The first electrode 471 is ring shaped. A voltage is applied between the first and second electrodes 471 and 472 to supply an electric current into the active layer 43 and thereby cause an emission of light. Since the first electrode 471 is ring shaped, the light thereby generated has a ring-shaped field distribution within the two-dimensional photonic crystal 45. Due to this field distribution, a radially polarized laser beam having a ring-shaped cross section is emitted from the two-dimensional photonic crystal 45. The laser beam thus generated can be focused by a focusing lens to make its diameter smaller than the diffraction limit. Such a laser beam is suitable for optical pickups and other optical devices.

### TECHNICAL FIELD

The present invention relates to a two-dimensional photonic crystal surface-emitting laser, which can be employed in an optical pickup whose spot size is equal to or smaller than the diffraction limit or a laser-beam processing having a high level of energy efficiency.

### BACKGROUND ART

In the field of optical storage devices, reducing the spot size of the laser beam used for recording (or writing) information into a recording medium or restoring (or reading) the information from the recording medium is required to increase the recording density on the recording medium. Simply focusing the laser beam by a beam-focusing unit including one or more focusing lenses cannot make the spot size of the laser beam equal to or smaller than the diffraction limit determined by the wavelength of the laser beam and the numerical aperture of the beam-focusing unit. Accordingly, in recent years, many techniques for achieving a spot size smaller than the diffraction limit have been researched. Such techniques are called the super-resolution technique.

Non-Patent Document 1 discloses a laser beam suitable for reducing the spot size. FIG. 1 schematically shows the cross section of the laser beam. The gray area 11 indicates where the light is present. The thick arrows indicate the direction of polarization. The laser beam has a ring-shaped cross section; the field strength is approximately zero at the center 12. The light is polarized from the center to the circumference (i.e. in the radial direction). Such a laser beam is called the “radial-polarized ring laser beam” hereinafter. Focusing a radial-polarized ring laser beam enables the generation of a beam spot having a beam diameter smaller than the diffraction limit.

Non-Patent Document 2 discloses a method and device for producing a radial-polarized ring laser beam. FIG. 2 shows the construction of the device, which includes the following components arranged in series: a He—Ne laser 21, photodiode 22, half-wave plate 23, first focusing lens 24, pinhole 25, first collimator lens 26, polzarization-converting plate 27, second focusing lens 28, non-confocal Fabry-Perot interferometer 29, second collimator lens 30, half mirror 31, aperture 32, objective lens 33 and sample stage 34. Located behind the half mirror 31 is a monitor diode 35 for detecting the light passing through the half mirror 31. The photodiode 22 and the half-wave plate 23 prevent retrogression of the laser beam generated by the He—Ne laser 21. The first focusing lens 24 and pinhole 25 are intended to give the laser beam a desired cross-sectional shape. The first and second collimator lenses 26 and 30 each produce a parallel beam of light from a non-parallel beam coming from the first or second focusing lens 24 or 28. The parallel beam thus produced is cast onto the polarization-converting plate 27 or aperture 32. The constructions of the polarization-converting plate 27 (FIG. 2(b)) and the aperture 32 (FIG. 2(c)) will be described later.

In this device, the He—Ne laser 21 generates a linearly polarized laser beam 1 (FIG. 3(a)). The laser beam 1 passes through the photodiode 22 and other components and reaches the polarization-converting plate 27. As shown in FIG. 2(b), the polarization-converting plate 27 has four sectors 271-274 divided by the angles of 90 degrees and arranged in a clockwise direction. Each sector consists of a half-wave plate whose fast axis is differently oriented. Specifically, the direction of the fast axis in the sector 271 is the same as that of the linear polarization of the incident laser beam (FIG. 3(a)), whereas the fast axes in the other three sectors 272, 273 and 274 are at angles of −45, 90 and +45 degrees from the aforementioned linear polarization, respectively. Due to the action of the half-wave plate 23, the polarization symmetrically changes in each sector with respect to the fast axis of that sector. As a result, in any of the sectors 271-274, the laser beam is polarized basically in the radial direction (FIG. 3(b)).

After passing through the polarization-converting plate 27, the laser beam travels through the second focusing lens 28 and other components and reaches the half mirror 31, which reflects the laser beam toward the aperture 32. The aperture 32 has a ring-shaped transparent area 322, which allows the passage of light, and the blocking areas 321 and 323, which block the laser beam outside the transparent area 322. The aperture 32 gives the laser beam a ring-shaped cross section (FIG. 3(c)). After passing through the aperture 32, the laser beam is focused by the objective lens 33. As stated earlier, the laser beam is polarized basically in the radial direction and has a ring-shaped cross section. Therefore, due to the super-resolution effect, the resultant laser beam can be focused to makes its spot size equal to or smaller than the diffraction limit, as described in Non-Patent Document 1.

A radially polarized laser beam can be suitably used in the field of metal-processing using a laser beam as well as in the super-resolution technique. Non-Patent Document 3 discloses the result of a calculation, which proves that an irradiation of a radially polarized laser beam onto a metal makes the processing speed higher than in the case of using a circularly or linearly polarized laser beam having the same energy level. According to that document, this is because metals have higher energy-absorbing efficiencies for radially polarized light than other kinds of polarized light.

[Non-Patent Document 1] S. Quabis et al., “Focusing light to a tighter spot”, Optics Communications, vol. 179, pp. 1-7

[Non-Patent Document 2] R. Dorn et al. “sharper Focus for a Radially Polarized Light Beam”, Physical Review letters, vol. 91, No. 23, pp. 233901-1-233901-4

[Non-Patent Document 3] V. G. Niziev et al., “Influence of beam polarization on laser cutting efficiency”, Journal of Physics D-Applied Physics, vol. 32, No. 13, pp. 1455-1461

### DISCLOSURE OF THE INVENTION

Problems to be Solved by the Invention

In the radial-polarized ring laser beam generator disclosed in Non-Patent Document 2, the four sections 271-274 of the polarization-converting plate 27 are designed to change the direction of polarization of the laser beam to a common direction within each of the four segments 361-364 of the beam's cross section (FIG. 3(c)) corresponding to the four sectors 271-274. According to this design, the direction of polarization at a position closer to one of the boundaries of the segments 361-364 will be more deviated from the radial direction. Therefore, in a strict sense, this laser beam is not radially polarized. The spot size of this laser beam cannot be as small as that of an ideal laser beam, which is radially polarized at any point within the cross section.

The radial-polarized ring laser beam generator disclosed in Non-Patent Document 2 uses a complex optical system including a large number of optical components to produce a radially polarized beam from a linearly polarized beam generated by the laser light source. Accordingly, this radial-polarized ring laser beam generator is very costly.

Thus, an objective of the present invention is to provide a two-dimensional photonic crystal surface-emitting laser that can generate a radially polarized laser beam having a ring-shaped cross section (i.e. a radial-polarized ring laser beam) without using a complex optical system and thereby contribute to the reduction of the device cost.

Means for Solving the Problems

To solve the previously described problems, the present invention provides a two-dimensional photonic crystal surface-emitting laser, which is characterized by:
a) an active layer;
b) a two-dimensional photonic crystal located on one side of the active layer, including a plate-shaped body material in which a large number of areas whose refractive index differs from that of the body material are periodically arranged; and
c) a pair of electrodes located on both sides of the active layer and the two-dimensional photonic crystal, including a ring-shaped first electrode located on the side closer to the active layer and a second electrode located on the side farther from the active layer.
   Effect of the Invention

The two-dimensional photonic crystal surface-emitting laser according to the present invention can generate a radial-polarized ring laser beam by itself. Since there is no need to use a complex optical system for converting the polarization, the total production cost of the radial-polarized ring laser beam generator is reduced. The laser beam thereby produced is radially polarized at any point within its cross section. Accordingly, the diameter of the laser beam can be reduced to achieve a spot size smaller than the diffraction limit. The spot size thereby achieved can be smaller than that achieved by the device disclosed in Non-Patent Document 2. Thus, a super-resolution laser beam having a diameter equal to or smaller than the diffraction limit is obtained.

A device for generating a super-resolution laser beam having a diameter equal to or smaller than the diffraction limit can be constructed by combining a two-dimensional photonic crystal surface-emitting laser according to the present invention and one or more focusing lenses for focusing the laser beam generated by the aforementioned laser into a laser beam having a diameter equal to or smaller than the diffraction limit. This super-resolution laser beam generator can be used as a light source in an optical pickup for recording information on an optical storage medium with high density or restoring information recorded on the optical storage medium with high density.

Furthermore, the two-dimensional photonic crystal surface-emitting laser according to the present invention can be used in a laser-beam processing as a light source for casting light onto an object to be worked. Since the light generated by this laser is radially polarized, the energy of the laser beam is efficiently supplied into the metal, so that the metal can be worked (cut, engraved, etc.) at high speeds. In the case of using the present laser in a laser-beam processing, it is unnecessary to focus the laser beam to makes its diameter equal to or smaller than the diffraction limit.

### BRIEF DESCRIPTION OF THE DRAWINGS

FIG. 1 is a cross-section view of a ring laser beam polarized in the radial direction.

FIGS. 2(a-c) are schematic diagrams showing the construction of a conventional device for producing a radial-polarized ring laser beam.

FIGS. 3(a) and 3(b) show the states of polarization of the laser beam observed while the beam is passing through the device shown in FIG. 2 (b), and FIG. 3(c) shows the state of polarization of the laser beam finally produced by the device.

FIG. 4 is a perspective view of an embodiment of the two-dimensional photonic crystal surface-emitting laser according to the present invention.

FIGS. 5(a) and 5(b) are perspective views of two-dimensional photonic crystals 45 and 45′ used in the surface-emitting laser of the present embodiment.

FIGS. 6(a) and 6(b) show the results of calculations of the electromagnetic field distribution within the two-dimensional photonic crystals used in the two-dimensional photonic crystal surface-emitting laser according to the present invention.

FIG. 7 shows the result of calculation of the field strength and the direction of polarization on a cross section of the laser beam generated by the two-dimensional photonic crystal surface-emitting laser according to the present invention.

FIG. 8 is a perspective view of a two-dimensional photonic crystal surface-emitting laser of a reference example.

FIG. 9 shows the result of calculation of the field strength and the direction of polarization on a cross section of the laser beam generated by the two-dimensional photonic crystal surface-emitting laser of the reference example.

FIG. 10(a) is a photograph showing a cross section of a laser beam generated by the two-dimensional photonic crystal surface-emitting laser of the reference example, and FIGS. 10(b-1)-10(b-4) are photographs each showing a cross section of the laser beam observed after the beam has passed through a linear-polarizing plate.

### EXPLANATION OF THE NUMERALS

1 . . . Laser beam
11 . . . Area where the light is present
12, 51 . . . Central zone of the laser beam (the area where the light is not present)
21 . . . He—Ne laser
22 . . . Photodiode
23 . . . Half-wave plate
24 . . . First focusing lens
25 . . . Pinhole
26 . . . First collimator lens
27 . . . Polarization-converting lens
271, 272, 273, 274 . . . Areas having fast axes differently oriented
28 . . . Second focusing lens
29 . . . Non-confocal Fabry-Perot interferometer
30 . . . Second collimator lens
31 . . . Half mirror
32 . . . Aperture
321 . . . Blocking area
322 . . . Transparent area
33 . . . Objective lens
34 . . . Sample stage
35 . . . Monitor diode
361, 362, 363, 364 . . . Segments of cross section of the laser beam, each having a different direction of polarization
41 . . . Substrate
411 . . . Upper surface
421 . . . Cladding layer
422 . . . Cladding layer
43 . . . Active layer
44 . . . Carrier-blocking layer
45, 45′ . . . Two-dimensional photonic crystal
451, 451′ . . . Body material
452, 452′ . . . Hole
46 . . . Contact layer
461 . . . Lower surface of the contact layer
471, 671 . . . First electrode
4711 . . . Central hole of the first electrode 471
472 . . . Second electrode
4721 . . . Window of the second electrode 472
63 . . . Active layer
711-714 . . . Direction of the polarized component of light that can pass through an optical filter
72 . . . Direction of the radial polarization
731-734 . . . portion where the direction of the radial polarization coincides with the direction of the polarized component of light that can pass through the optical filter

### BEST MODE FOR CARRYING OUT THE INVENTION

The two-dimensional photonic crystal surface-emitting laser (which is simply called the “surface-emitting laser” hereinafter) according to the present invention has a two-dimensional photonic crystal located on one side of an active layer. A pair of electrodes is provided on both sides of the active layer and the two-dimensional photonic crystal. It is possible to add a spacer or similar member between the active layer, the two-dimensional photonic crystal and the electrodes.

The active layer may be the same as those conventionally used in conventional Fabry-Perot laser light sources. The two-dimensional photonic crystal in the present invention consists of a plate-shaped body material in which areas whose refractive index differs from that of the body material (which is called the “modified refractive index areas” hereinafter) are periodically arranged. The modified refractive index areas can be arranged in a square or triangular lattice pattern or some other pattern. An example of the modified refractive index area is a hole. This form is preferable in that it creates a large difference in refractive index between the modified refractive index area and the body material and is easy to manufacture. Alternatively, the modified refractive index area may be created by embedding some member into the body material. This form of modified refractive index area is suitable for preventing a heat deformation of the modified refractive index area, which can take place if the two-dimensional photonic crystal needs to be adhered to another layer at a high temperature during the manufacturing process. The modified refractive index area consisting of an embedded member is also suitable for the case where a new layer is to be epitaxially grown after the photonic crystal is created during the manufacturing process.

Minimally, the electrode located on the side closer to the active layer (i.e. the first electrode) must be a ring electrode having a hole at its center. Both the circumference and the hole of the ring electrode may be circular, square, hexagonal or any other form.

The surface-emitting laser according to the present invention operates as follows: When a voltage is applied between the first and second electrodes, an electric current flows into the active layer and causes an emission of light in that layer. This light forms a standing wave within the two-dimensional photonic crystal and is thereby amplified. As a result, a laser beam is generated to the direction perpendicular to the surface of the two-dimensional photonic crystal.

In the surface-emitting laser according to the present invention, since the first electrode located closer to the light-emitting layer is ring shaped, the electric current flowing into the light-emitting layer also has a ring-shaped field distribution in which the current in a circumferential zone around the center of the light-emitting layer is stronger than that at the center. Accordingly, the field distribution of the light emitted from that layer is also ring shaped. The light having such a field distribution creates a resonance mode in the two-dimensional photonic crystal, where the magnitude of the envelope of the amplitude of the electromagnetic waves is zero at the center of the crystal surface. The resultant laser beam has a ring-shaped cross section where the field strength is zero at its center. The direction of polarization of this laser beam is radial.

The present invention has published a paper titled “Nijigen Fotonikku Kesshou Menhakkou Leezaa No Denkyoku Kouzou Oyobi Jissou Houhou No Kaizen (Improvements of Electrodes Structure of Two-Dimensional Photonic Crystal Surface-Emitting Laser and Its implementation Method)” (Wataru KUNISHI et al., Preprints of the Symposia of the 66^{th} Meeting of the Japan Society of Applied Physics in Autumn 2005, vol. 3, Symposium No. 9p-H-4), which discloses a two-dimensional photonic crystal surface-emitting laser using a window-shaped electrode having a central window (or hole). The ring electrode of the present embodiment differs from the window-shaped electrode disclosed in the aforementioned paper in that the former electrode is the first electrode, which is located closer to the active layer, whereas the latter is the second electrode, which is located farther from the active layer. Another difference exists in that the former electrode is intended to produce a radial-polarized ring laser beam, whereas the latter is intended to provide a passage for the laser beam. For the same reason as described in the aforementioned paper, it is desirable to use a window-shaped electrode as the second electrode of the present invention.

The radial-polarized ring laser beam generated by the surface-emitting laser according to the present invention can be focused by one or more focusing lenses to make its diameter smaller than the diffraction limit, as described in Non-Patent Document 1.

### EMBODIMENT

(1) Embodiment of the Two-Dimensional Photonic Crystal Surface-Emitting Laser According to the Present Invention

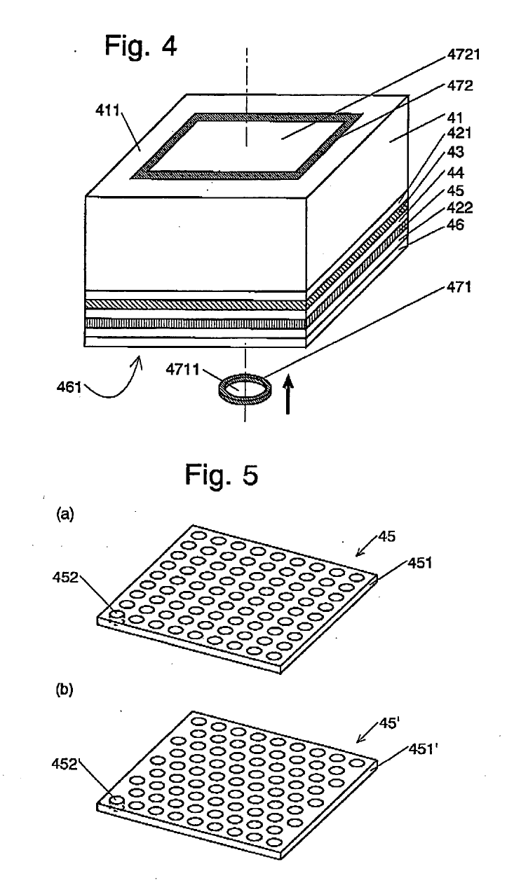

An embodiment of the surface-emitting laser according to the present invention is described with reference to FIGS. 4, 5(a) and 5(b).

FIG. 4 is a perspective view of the surface-emitting laser of the present embodiment. It includes a substrate 41 made of an n-type gallium-arsenide (GaAs) semiconductor, which is backed by a cladding layer 421 made of an n-type aluminum gallium-arsenide (AlGaAs) semiconductor. Located under this layer is an active layer 43, in which a multiple-quantum well (MQW) made of indium gallium-arsenide (InGaAs)/gallium-arsenide (GaAs) is present. The active layer 43 is supported by a carrier-blocking layer 44 made of AlGaAs, under which a two-dimensional photonic crystal 45 is provided. The two-dimensional photonic crystal 45 in the present embodiment consists of a plate-shaped body material 451 made of p-type GaAs in which cylindrical holes 452 are periodically arranged in a square lattice pattern (FIG. 5(a)). Located under the two-dimensional photonic crystal 45 is a cladding layer 422 made of p-type AlGaAs and a contact layer 46 made of p-type GaAs.

The substrate 41 is considerably thicker than any other layers. This is to make the distance between the lower surface 461 of the contact layer 46 and the active layer 43 adequately smaller than the distance between the upper surface 411 of the substrate 41 and the active layer 43.

A first electrode 471 is provided at the center of the lower surface 461 of the contact layer 46. The first electrode 471 is a ring electrode having a central hole 4711 in which no electrode material is present. As explained earlier, the hole 4711 is intended to create a ring-shaped field distribution of the electric current flowing into the active layer 43. A second electrode 472 having a central window 4721 is located on the upper surface 411 of the substrate 41. The window 4721 is intended to be a passage for the laser beam emitted from the surface-emitting laser of the present embodiment.

The surface-emitting laser of the present embodiment operates as follows: When a voltage is applied between the first and second electrodes 471 and 472, holes and electrons flow into the active layer 43, in which the holes recombine with the electrons, causing an emission of light. Since the first electrode 471 located closer to the active layer 43 is ring shaped, the density distribution of the holes and electrons inside the active layer 43 is also ring shaped, and so is the emitted field. A specific wavelength component of light generated in the active layer 43 is intensified due to interference within the two-dimensional photonic crystal 45, causing a laser oscillation. The laser light thus generated is emitted from the surface of the substrate 41 through the window 4721 to the outside. The laser beam thus emitted is a radial-polarized ring laser beam.

The first electrode 471, which is a circular ring in FIG. 4, may be changed to a rectangle or any other form as long as it is ring shaped. The second electrode 472, which is a window-shaped electrode in FIG. 4, may be replaced with an electrode having the electrode material also in its central portion. In this case, the second electrode 472 should be made of a material transparent to the laser beam. The periodic structure of the two-dimensional photonic crystal may be different from the previous one in which the holes were arranged in the square lattice pattern. For example, FIG. 5(b) shows another two-dimensional photonic crystal 45′, which consists of a body material 451′ with holes 452′ arranged in a triangular lattice pattern.

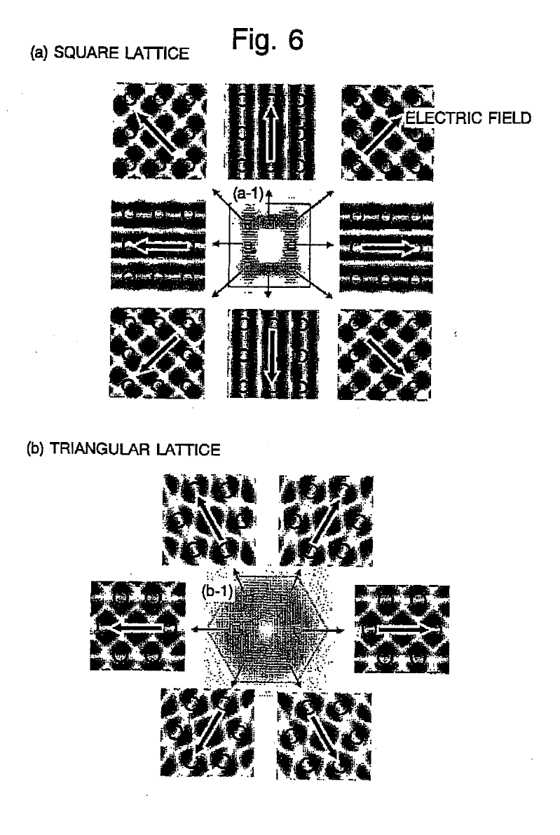

FIGS. 6(a) and 6(b) each show an electromagnetic field distribution within the two-dimensional photonic crystal of the surface-emitting laser, calculated by a finite difference time domain (FDTD) method, where (a) uses the two-dimensional photonic crystal 45 and (b) uses the two-dimensional photonic crystal 45′. The diagrams (a-1) and (b-1) at the centers of FIGS. 6(a) and 6(b) each show the entire photonic crystal. The other pictures surrounding the two diagrams are enlarged views of the sections indicated by the squares in (a-1) and (b-1). In the surrounding pictures, the gray shading (dark/light) shows the magnetic field strength (strong/weak) and the arrows indicate the oscillating directions of the electric field. Both FIGS. 6(a) and 6(b) show that the electric field is oscillating in the radial direction, from the center (indicated by “X” in FIGS. 6(a) and 6(b)) to the circumference of the two-dimensional photonic crystal.

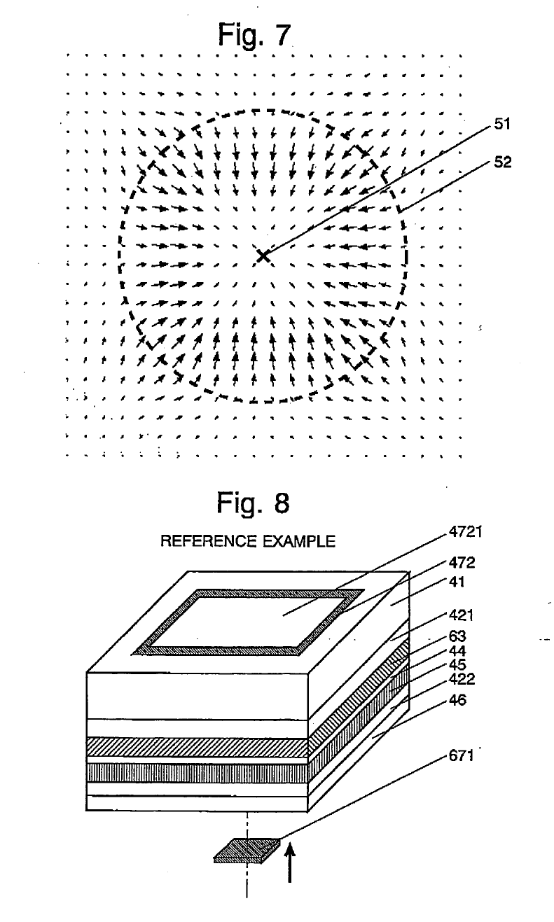

FIG. 7 shows the field strength and the direction of polarization on a cross section of the laser beam generated by the surface-emitting laser using the two-dimensional photonic crystal 45, calculated by an FDTD method. In FIG. 7, the length of each arrow indicates the field strength, and the direction of each arrow indicates the direction of polarization. The calculation result shows that the laser beam has a ring-shaped cross section in which the field strength is zero within a small zone including the center 51 and takes finite values around that zone. At least within the area 52 shown in FIG. 7, the direction of polarization at any point coincides with the radial direction extending from the center 51. These results prove that the laser beam generated by the surface-emitting laser of the present embodiment is a radial-polarized ring laser beam.

(2) Reference Example

FIG. 8 shows an example of the surface-emitting laser that can generate a radial-polarized ring laser beam. This example is not a surface-emitting laser according to the present invention. The surface-emitting laser of the present example uses a first electrode 671 with no central hole. When an electric current is supplied, the active layer 63 hereby used generates a TM-polarized light whose electric field oscillates in the direction perpendicular to that layer. The components other than the first electrode 671 and the active layer 63 are the same as those used in the previous embodiment.

In many two-dimensional photonic crystal surface-emitting lasers, the active layer 63 is designed to generate a TE-polarized light whose electric field oscillates in a direction parallel to that layer because this design can achieve a large gain. In this case, the laser oscillation is produced by generating a TE-polarized light in the active layer and causing a diffraction and interference of that light within the two-dimensional photonic crystal. The resultant laser beam emitted from the two-dimensional photonic crystal has a ring-shaped cross section in which the electric field of the light oscillates in the tangential direction. In contrast, in the reference example, the laser oscillation is produced by generating a TM-polarized light in the active layer and causing a diffraction and interference of that light within the two-dimensional photonic crystal. The resultant laser beam emitted from the two-dimensional photonic crystal has a ring-shaped cross section in which the magnetic field of the light oscillates in the tangential direction. Since the oscillating direction of the magnetic field is perpendicular to that of the electric field, the oscillating direction of the electric field in this laser beam, i.e. the direction of polarization, coincides with the radial direction. Thus, it is possible to produce a radial-polarized ring laser beam without using the ring-shaped first electrode.

An example of the active layer for generating a TM-polarized light is GaInAs/GaInAsP.

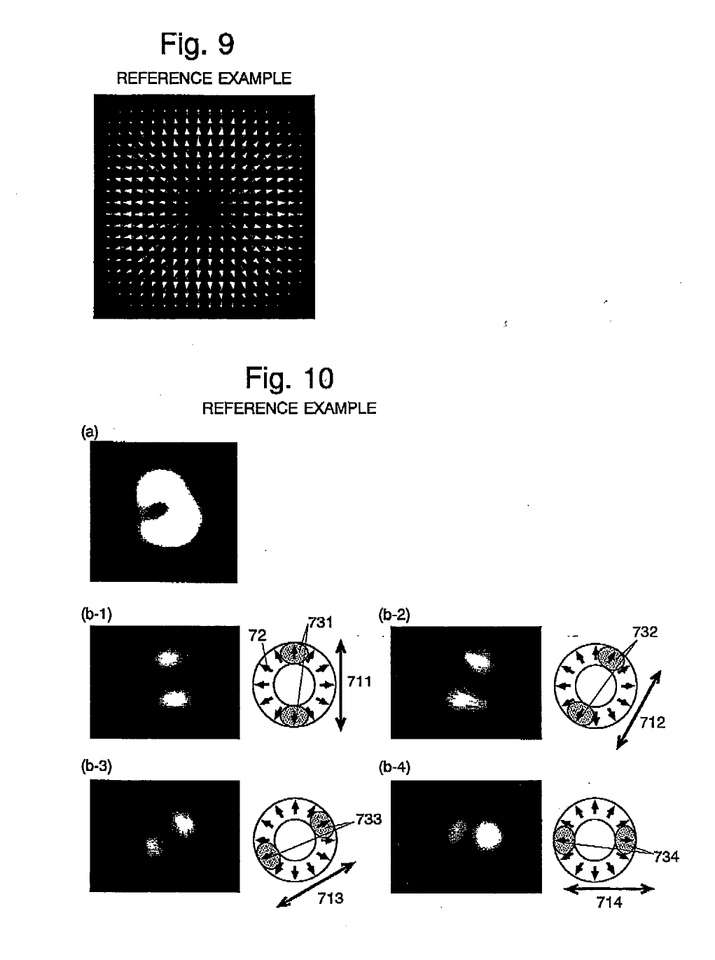

FIG. 9 shows the field strength and the direction of polarization on a cross section of the laser beam generated by the surface-emitting laser of the reference example, calculated by an FDTD method. In this figure, the length of each arrow indicates the field strength, and the direction of each arrow indicates the direction of polarization. The figure shows that the field strength is zero at the center of the cross section of the laser beam and takes finite values around the center, and the direction of polarization is radial. These results prove that the laser beam obtained in this example is a radial-polarized ring laser beam.

FIG. 10(a) is a photograph showing a cross section of the laser beam generated by the surface-emitting laser of the reference example. This photograph shows that the laser beam hereby obtained has a ring-shaped cross section.

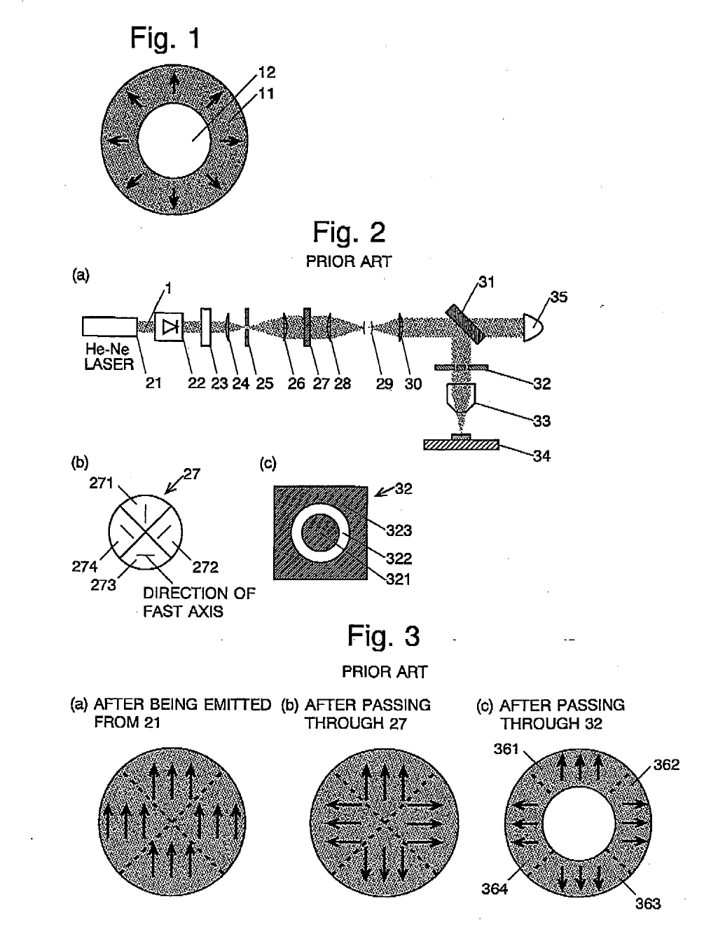

FIGS. 10(b-1)-10(b-4) are photographs each showing a cross section of the laser beam observed after the beam has passed through a polarizing filter that allows the passage of only a component of light polarized in the direction indicated by the arrows 711-714. Any of these photographs shows that the light is passing only at specific portions 731-734 where the direction of the radial polarization (i.e. the direction indicated by the arrows 72) coincides with the direction 711-714 of the component of light that can pass through the polarizing filter. These photographs prove that the laser beam hereby obtained is radially polarized.

1. A two-dimensional photonic crystal surface-emitting laser, comprising:
a) an active layer;
b) a two-dimensional photonic crystal located on one side of the active layer, including a plate-shaped body material in which a large number of areas whose refractive index differs from that of the body material are periodically arranged; and
c) a pair of electrodes located on both sides of the active layer and the two-dimensional photonic crystal, including a ring-shaped first electrode located on a side closer to the active layer and a second electrode located on a side farther from the active layer.

2. The two-dimensional photonic crystal surface-emitting laser according to claim 1, wherein the second electrode is a window-shaped electrode having a window at its center for allowing a passage of laser light.

3. A super-resolution laser beam generator, comprising:
a two-dimensional photonic crystal surface-emitting laser according to claim 1; and
a focusing lens for focusing a laser beam generated by the two-dimensional photonic crystal surface-emitting laser, to make its diameter equal to or smaller than a diffraction limit.

4. An optical pickup, comprising the super-resolution laser beam generator according to claim 3 as a light source.

5. A laser-beam processing, comprising the two-dimensional photonic crystal surface-emitting laser according to claim 1 as a light source for casting light onto an object to be worked.

6. A super-resolution laser beam generator, comprising:
a two-dimensional photonic crystal surface-emitting laser according to claim 2; and
a focusing lens for focusing a laser beam generated by the two-dimensional photonic crystal surface-emitting laser, to make its diameter equal to or smaller than a diffraction limit.

7. A laser-beam processing, comprising the two-dimensional photonic crystal surface-emitting laser according to claim 2 as a light source for casting light onto an object to be worked.
